(19) United States
(12) Patent Application Publication
(10) Pub. No.: US 2026/0082523 A1
(43) Pub. Date: Mar. 19, 2026

(54) COOLING CABINET

(71) Applicant: LITE-ON TECHNOLOGY CORPORATION, Taipei (TW)

(72) Inventors: Pin-Chiao TSENG, Taipei (TW); Wen-Chi Chen, Taipei (TW); Shu-Hua Mau, Taipei (TW)

(21) Appl. No.: 19/291,661

(22) Filed: Aug. 6, 2025

Related U.S. Application Data
(60) Provisional application No. 63/694,937, filed on Sep. 16, 2024.

(30) Foreign Application Priority Data
Jun. 12, 2025 (TW) 114122062

(51) Int. Cl. H05K 7/20

(52) U.S. Cl. CPC H05K 7/20781; H05K 7/20836

(57) ABSTRACT

A cooling cabinet includes a rack module, a cooling module and a pump module. The rack module includes a bottom plate and an engaging portion, wherein the engaging component is fixed to the bottom plate. The cooling module is disposed on the rack module. The pump module is disposed on the rack module and is selectively connected to or disconnected from the cooling module, and includes a sliding plate, a containing housing, a pump, an inverter and a handle. The sliding plate is slidably connected to the bottom plate. The pump is disposed on the sliding plate. The inverter is electrically connected to the pump and is disposed on the containing housing. The handle is pivotally connected to the containing housing and includes a limiting end. When the pump module is connected to the cooling module, the limiting end of the handle interferes with the engaging component.

This application claims the benefit of U.S. provisional application Ser. No. 63/694,937, filed Sep. 16, 2024, the subject matter of which is incorporated herein by reference, and claims the benefit of Taiwan application Serial No. 114122062, filed Jun. 12, 2025, the subject matter of which is incorporated herein by reference.

### BACKGROUND OF THE INVENTION

### Field of the Invention

The invention relates in general to a cooling cabinet for cooling a server.

### Description of the Related Art

In order to cool down electronic devices which generate heat when works, a liquid-cool type cooling cabinet is often used for achieving the desired cooling purpose. However, the cooling cabinet includes a pump and numerous pipelines, and the pump is disposed among these pipelines, and thus it makes maintenance difficult.

### SUMMARY OF THE INVENTION

The present disclosure relates to a display device, a light-emitting module thereof and a driving method thereof, which may improve the aforementioned conventional problems.

According to an embodiment of the present invention, a cooling cabinet is provided. The cooling cabinet includes a rack module, a cooling module and a pump module. The rack module includes a first bottom plate and a first engaging element, wherein the first engaging element is fixed to the first bottom plate. The cooling module is disposed in the rack module. The pump module is disposed in the rack module and selectively connected with or disconnected from the cooling module, and includes a first sliding plate, a pivot device, a first pump and a first handle. The first sliding plate is slidably connected to the first bottom plate. The pivot device is disposed on the first sliding plate. The first pump is disposed on the first sliding plate. The first handle is pivotally connected to the pivot device and includes a first limiting end. When the pump module is connected to the cooling module, the first limiting end of the first handle interferes with the first engaging element.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a functional block diagram of a cooling cabinet according to an embodiment of the present disclosure;

FIGS. 2A and 2B illustrate schematic diagrams of the cooling cabinet in FIG. 1 at different perspectives;

FIGS. 2C and 2D illustrate schematic diagrams of a portion of an interior of the cooling cabinet in FIG. 2B at two different perspectives;

FIG. 3A illustrates a schematic diagram of a connection between a pump module and a cooling module in FIG. 2B;

FIG. 3B illustrates an exploded view of a first pivot device in FIG. 3A;

FIG. 4A illustrates a schematic diagram of a cross-sectional view of the cooling cabinet in FIG. 3A along a direction 4A-4A′;

FIG. 4B illustrates a schematic view of the contact between the handle of the pump module and the engaging component of the rack module in FIG. 4A;

FIG. 4C1 and 4C2 illustrate schematic views of the separation between the pump module and the cooling module in FIG. 4B;

FIG. 5 illustrates an exploded view of the pump module in FIG. 4C2;

FIG. 6 illustrates a schematic diagram of the pump module FIG. 2B connected to the cooling module;

FIG. 7 illustrates a schematic diagram of the fluid path of the cooling module in FIG. 1;

FIG. 8 illustrates a fluid path configuration diagram of the main liquid tank, the liquid replenishment tank, the liquid replenishment pump and an expansion liquid tank in FIG. 7;

FIG. 9 illustrates a schematic diagram of a base of the rack module in FIG. 2A;

FIG. 10 illustrates a schematic diagram of a cross-sectional view of the base of the rack module in FIG. 9 along a direction 10-10′;

FIG. 11 illustrates a schematic diagram of a cross-sectional view of the base of the rack module in FIG. 9 along a direction 11-11′; and

FIG. 12 illustrates a schematic diagram of the configuration of the second liquid leakage detection line according to an embodiment of the present invention.

### DETAILED DESCRIPTION OF THE INVENTION

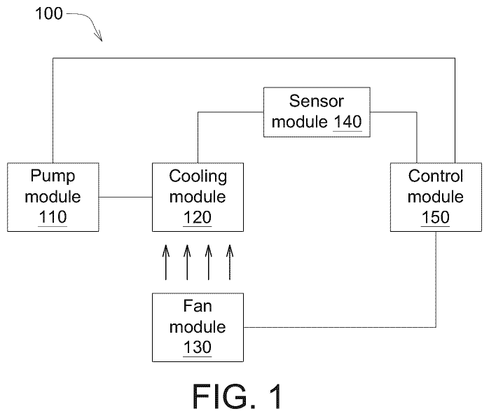

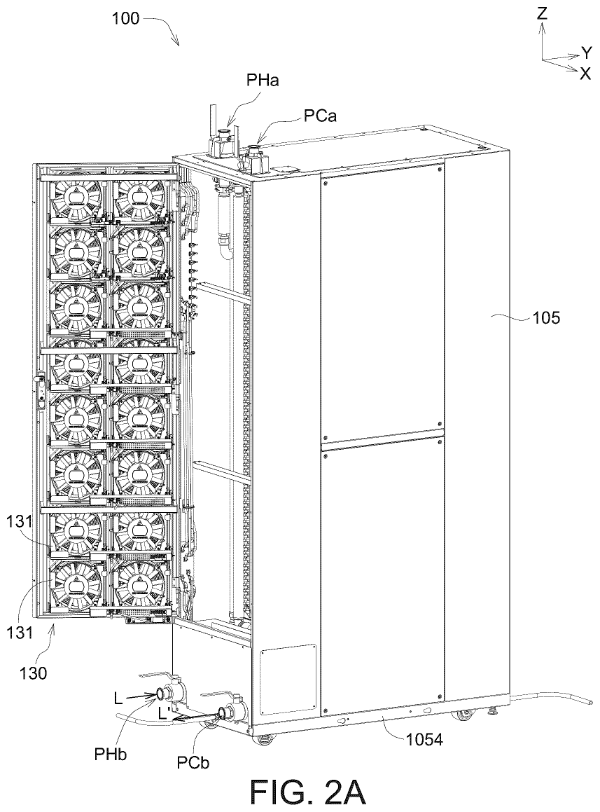

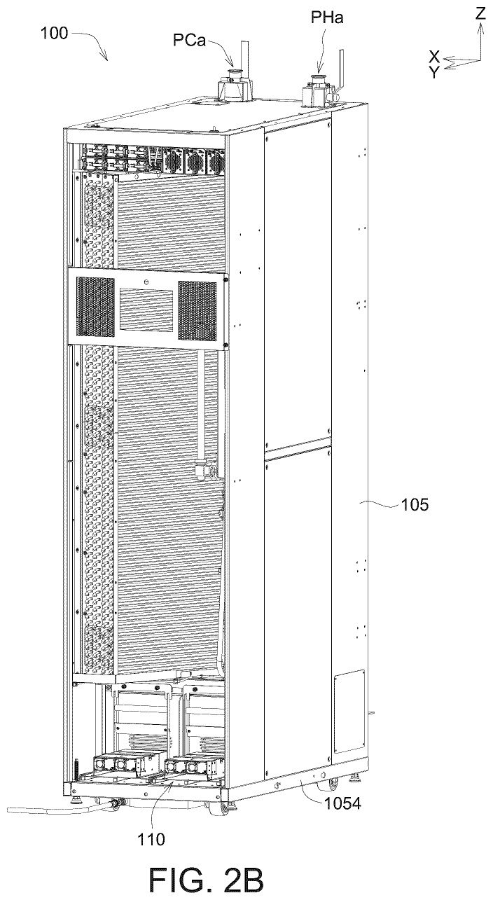

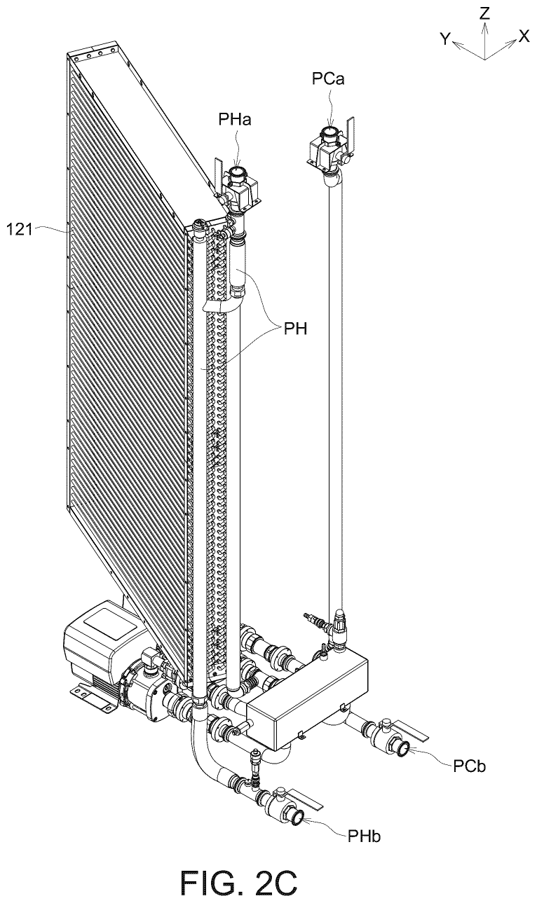

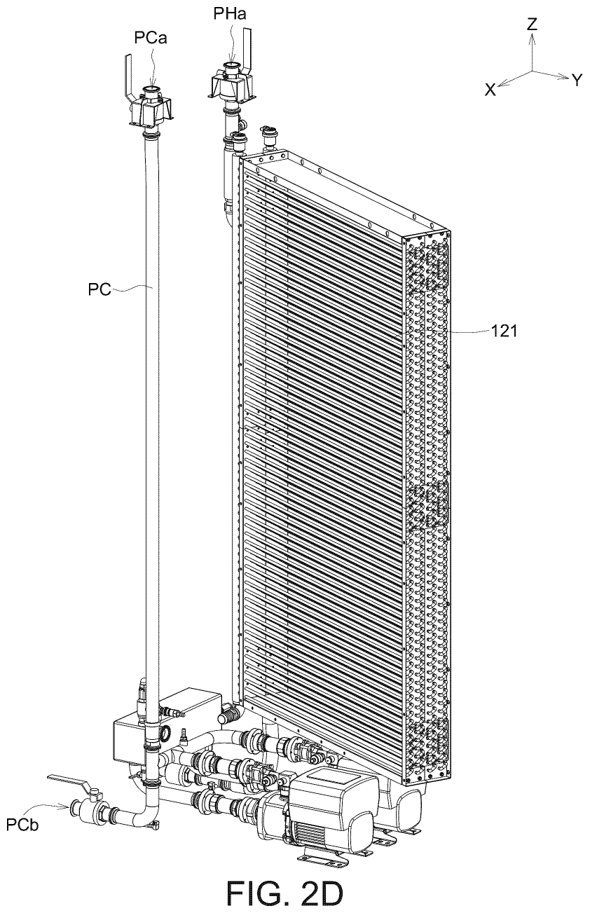

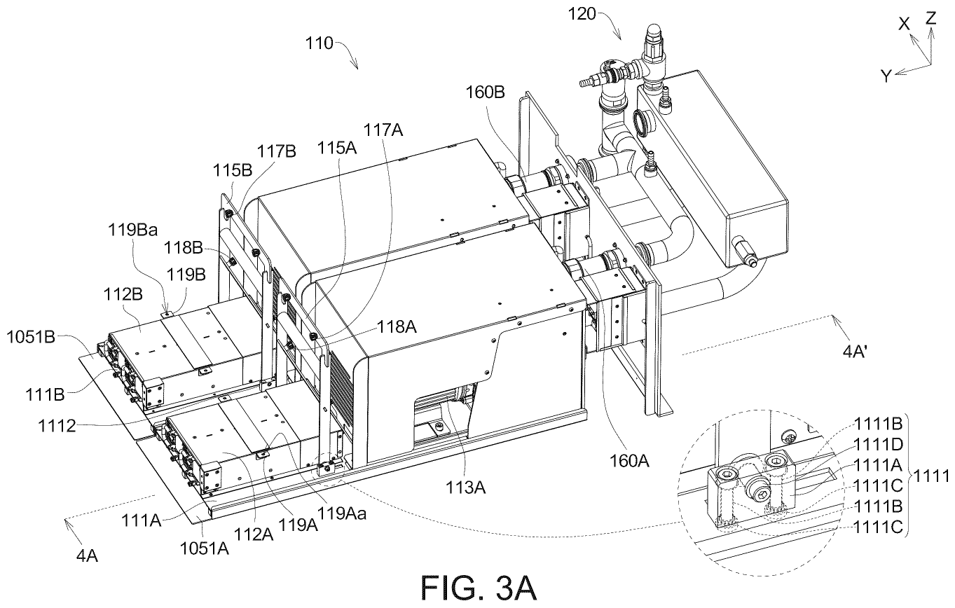

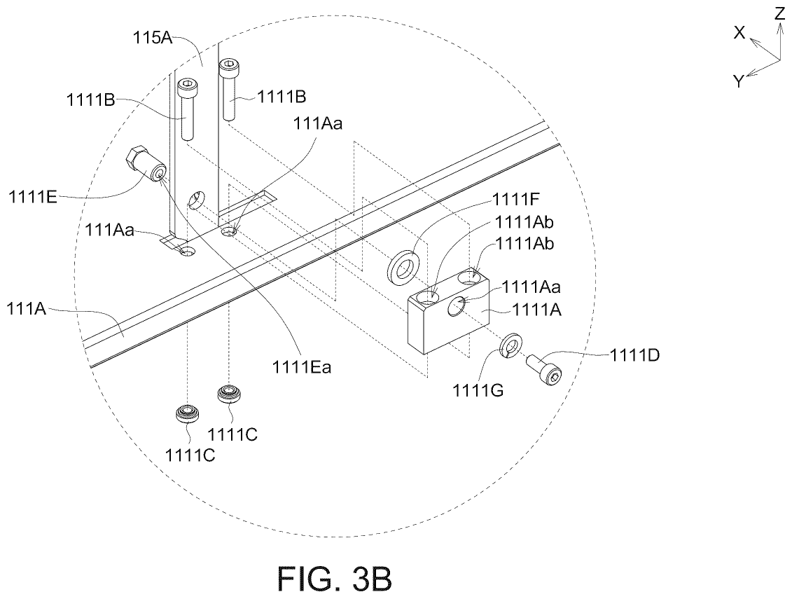

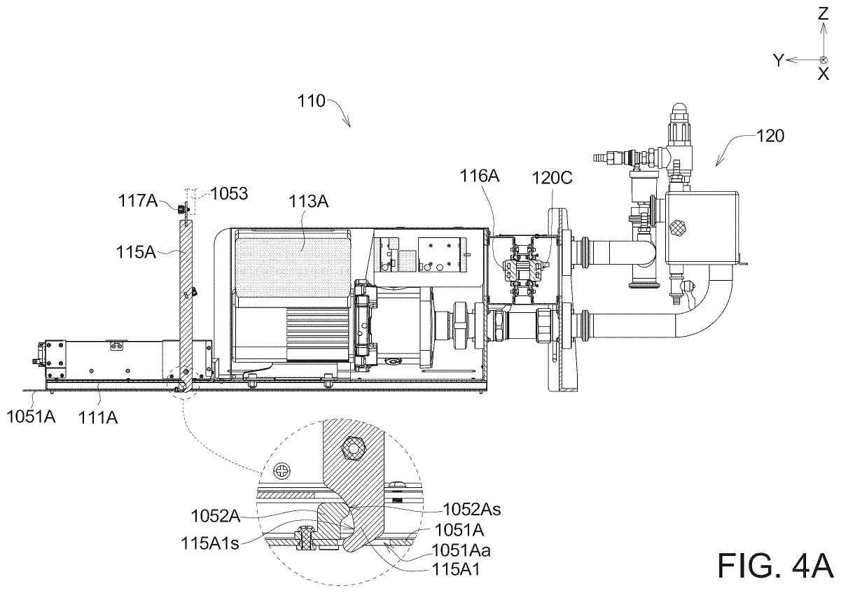

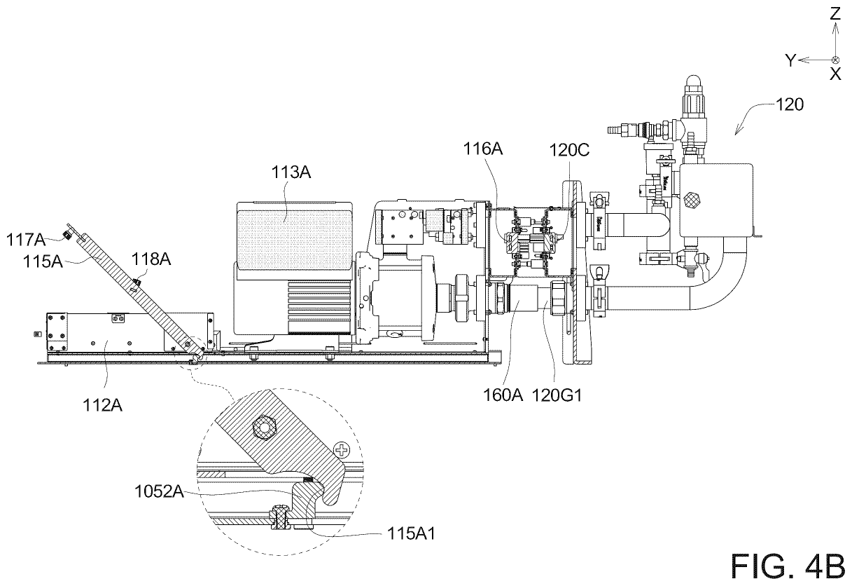

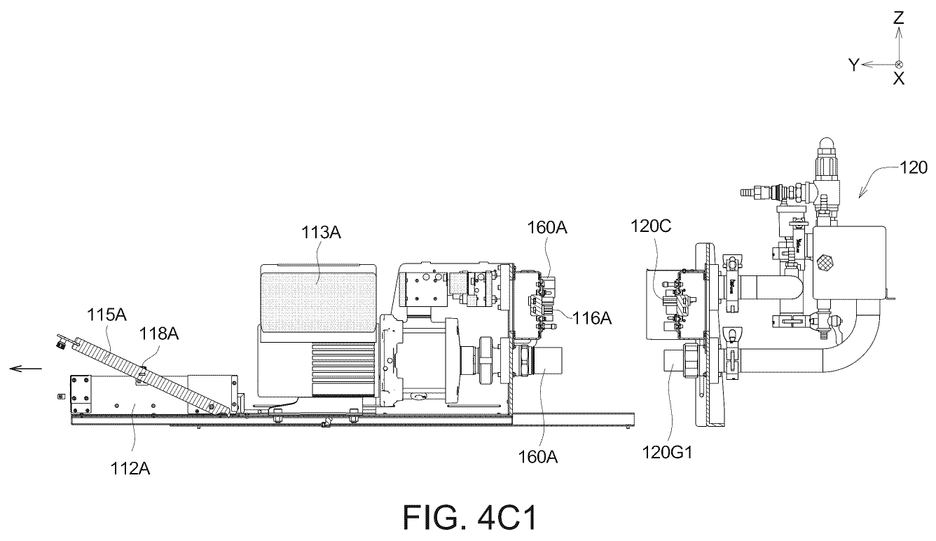

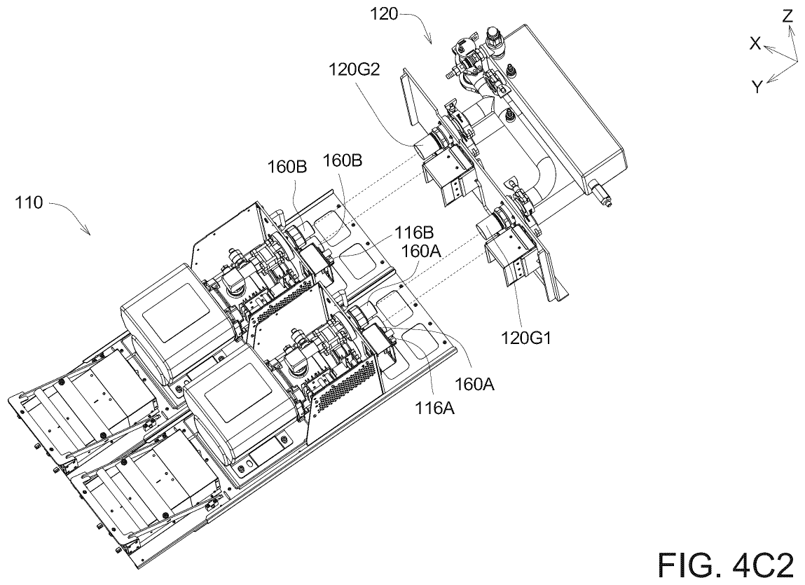

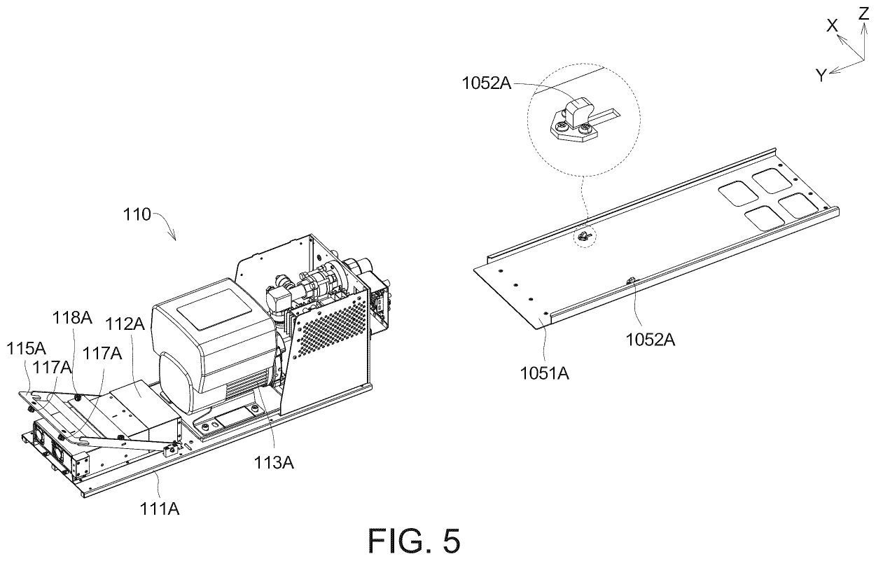

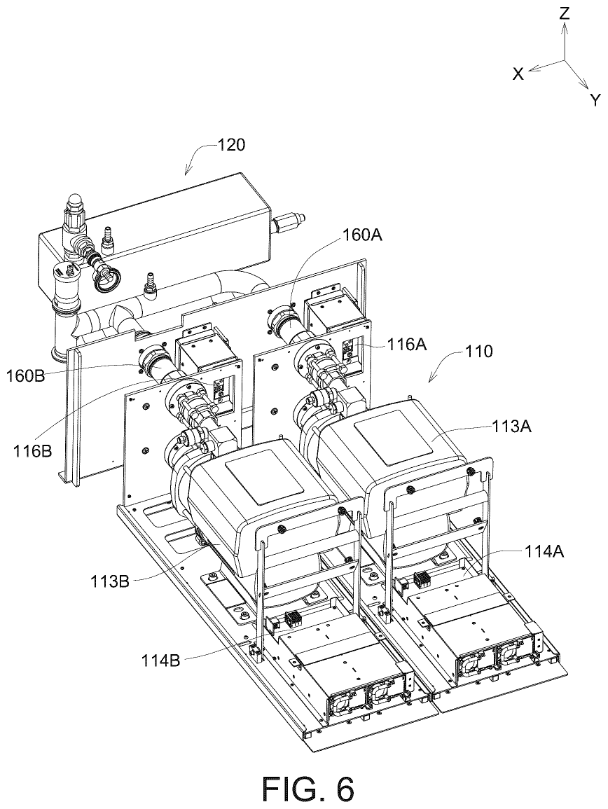

Referring to FIGS. 1 to 6, FIG. 1 illustrates a functional block diagram of a cooling cabinet 100 according to an embodiment of the present disclosure. FIGS. 2A and 2B illustrate schematic diagrams of the cooling cabinet 100 in FIG. 1 from different perspectives. FIGS. 2C and 2D illustrate schematic diagrams of a portion of an interior of the cooling cabinet 100 in FIG. 2B at two different perspectives. FIG. 3A illustrates a schematic diagram of a connection between a pump module 110 and a cooling module 120 in FIG. 2B. FIG. 3B illustrates an exploded view of a first pivot device 1111 shown in FIG. 3A. FIG. 4A illustrates a cross-sectional view of the cooling cabinet 100 along a direction 4A-4A′ in FIG. 3A. FIG. 4B illustrates a schematic view of the contact between the handle of the pump module 110 and the engaging component of the rack module 105 in FIG. 4A. FIG. 4C1 and 4C2 illustrate schematic views of the separation between the pump module 110 and the cooling module 120 in FIG. 4B. FIG. 5 illustrates an exploded view of the pump module 110 in FIG. 4C2. FIG. 6 illustrates a schematic diagram of the pump module 110 FIG. 2B connected to the cooling module 120.

The cooling cabinet 100 is configured to cool an electronic device (not shown), such as a server, such as cloud servers, artificial intelligence (AI) servers, big data servers or other electronic devices with high-power or high-heat-generating.

As shown in FIG. 1, the cooling cabinet 100 includes the rack module 105, the pump module 110, the cooling module 110, a fan module 130, a sensor module 140, and a control module 150. The pump module 110 may be selectively connected to or detachable from the cooling module 120. When the pump module 110 and the cooling module 120 are changed from a separation state to a connection state, a fluid path and an electrical-path between the pump module 110 and the cooling module 120 may be simultaneously connected. When the pump module 110 and the cooling module 120 are changed from the connection state to the separation state, the fluid path and the electrical-path between the pump module 110 and the cooling module 120 may be simultaneously disconnected. In addition, the fan module 130 and the sensor module 140 are electrically connected to the control module 150 to transmit signals to the control module 150 and/or be controlled by the control module 150. The fan module 130 includes at least one fan 131 (shown in FIG. 2A) which may be electrically connected to the control module 150. The sensor module 140 is connected to the cooling module 120 to detect temperature, pressure, flow rate and/or liquid level (or water level), liquid leakage and other information in the fluid path of the cooling module 120. Although not shown, the control module 150 includes a controller and a human-machine interface(HMI), wherein the human-machine interface is electrically connected to the controller. The controller may receive a signal from at least one of the electronic components of the cooling cabinet 100 and/or control at least one of the electronic elements of the cooling cabinet 100. Through the human-machine interface, the user may monitor the operating status of the cooling cabinet 100 and control the electronic elements of the cooling cabinet 100, and the electronic elements are, for example, servers. By driving the pump module 110 via the control module 150, the coolant in the coolant circuit of the cooling module is delivered to the electronic components to absorb the heat they generate. The temperature of the coolant will gradually increase, and then the high-temperature coolant will be returned to the pipe of the cooling module, and the heat of the coolant may be dissipated by a forced convection generated by the fan module 130.

As shown in FIGS. 2A, 2B, 3A and 5, the rack module 105 includes at least one bottom plate (for example, a first bottom plate 1051A and a second bottom plate 1051B) and at least one engaging element (for example, at least one first engaging element 1052A and at least one second engaging element (not shown)). The cooling module 120 is installed within the rack module 105. The pump module 110 is disposed in the rack module 105 and may be selectively connected to or disconnected from the cooling module 120. The pump module 110 includes at least one sliding plate (for example, a first sliding plate 111A and a second sliding plate 111B), at least one accommodating housing (for example, a first accommodating housing 112A and a second accommodating housing 112B), at least one pump (for example, a first pump 113A and a second pump 113B), at least one inverter (for example, a first inverter 114A and a second inverter 114B) are disposed in the accommodating housing, at least one handle (for example, a first handle 115A and a second handle 115B) and at least one pivot device (for example, at least one first pivot device 1111 and at least one second pivot device 1112).

As shown in FIGS. 3A and 3B, two first pivot devices 1111 are respectively disposed on opposite two sides of the first accommodating housing 112A. Each first pivot device 1111 includes a fixing box 1111A, at least one fixing element 1111B, at least one nut 1111C, a limiting element 1111D, a pivot element 1111E, a first gasket 1111F and a second gasket 1111G.

As shown in FIGS. 3A and 3B, in an embodiment, the fixed box 1111A is fixed to the first sliding plate 111A, and the pivot element 1111E is fixed to the first handle 115A and pivoted to the fixed box 1111A. As a result, the first handle 115A may rotate relative to the fixed box 1111A. The fixed box 1111A has a through hole 1111Aa extending along the X-axis, so that the first handle 115A may rotate along the X-axis. In addition, due to the limitation of the through hole 1111Aa, the first handle 115A may only rotate along the X-axis and cannot move along X-axis, Y-axis or Z-axis.

As shown in FIGS. 3A and 3B, the limiting element 1111D is fixed to the pivot element 1111E to prevent the pivot element 1111E from being separated from the fixed box 1111A along the +X-axis. Although not shown, the limiting element 1111D has an external thread (or male thread), and the pivot element 1111E has a screw hole 1111Ea, and the limiting element 1111D and the pivot element 1111E are fixed to each other by screwing. The limiting element 1111D and the pivot element 1111E are respectively located on opposite two sides of the fixed box 1111A to prevent the limiting element 1111D being separated from the pivot element 1111E. The first gasket 1111F is located between the fixed box 1111A and the pivot element 1111E, and the second gasket 1111G is located between the fixed box 1111A and the limiting element 1111D.

As shown in FIGS. 3A and 3B, the fixing element 1111B may fix the relative position between the fixing box 1111A and the first sliding plate 111A. For example, the fixing element 1111B passes through a through hole 1111Ab of the fixing box 1111A and the through hole 111Aa of the first sliding plate 111A. The nut 1111C is screwed on the fixing element 1111B to fix the relative position between the fixing box 1111A and the first sliding plate 111A. In the present embodiment, the through hole 1111Ab of the fixing box 1111A extends along Z-axis. In an embodiment, the fixing element 1111B is, for example, a bolt.

In addition, as shown in FIG. 3A, two second pivot devices 1112 (in FIG. 3A, only one second pivot device 1112 may be seen) are respectively disposed on opposite two sides of the second accommodating housing 112B. The second pivot device 1112 includes the structure the same as or similar to that of the first pivot device 1111, and therefore will not be described in detail herein. The connection method between the second pivot device 1112 and the second sliding plate 111B is the same as or similar to the connection method between the first pivot device 1111 and the first sliding plate 111A. The connection method between the second handle 115B and the second pivoting device 1112 is the same as or similar to the connection method between the first handle 115A and the first pivot device 1111, and therefore will not be described in detail herein.

The engaging element is fixed to the bottom plate. The sliding plate is slidably connected to the bottom plate. The pump is disposed on the sliding plate. The inverter is electrically connected to the pump and disposed in the accommodating housing. The handle includes a limiting end. When the pump module is connected to the cooling module, the limiting end of the handle is engaged with the engaging element to prevent the pump module 110 from being easily separated from the rack module 105. The following further illustrates an example.

As shown in FIGS. 3A, 4A and 5, the first engaging element 1052A is fixed to the first base plate 1051A, and the second engaging element (not shown) is fixed to the second base plate 1051B. The structure, function and/or configuration position of the second engaging element (not shown) are similar to the structure, function and/or configuration position of the first engaging element 1052A, and therefore will not be described in detail herein. The first sliding plate 111A is slidably connected to the first base plate 1051A, and the second sliding plate 111B is slidably connected to the second base plate 1051B. The first pump 113A is disposed and locked on the first sliding plate 111A, and the second pump 113B is disposed and locked on the second sliding plate 111B. The first inverter 114A is electrically connected to the first pump 113A and is disposed in the first accommodating housing 112A, and is locked on the first sliding plate 111A. The second pump 113B is disposed and locked on the second sliding plate 111B. The second inverter 114B is electrically connected to the second pump 113B and is disposed in the second accommodating housing 112B and is locked on the second sliding plate 111B.

As shown in FIG. 4C1, the first handle 115A includes a first limiting end 115A1, and the second handle 115B includes a second limiting end (not shown). The structure of the second limiting end is similar to or the same as the first limiting end 115A1, and it will not be repeated here. Thus, when the first limiting end 115A1 of the first handle 115A interferes with the first engaging element 1052A, the pump module 110 may be connected to the cooling module 120 by the interference force, as shown in FIG. 4A. Similarly, when the second limiting end (not shown) of the second handle 115B interferes with the second engaging element (not shown), the pump module 110 may be connected to the cooling module 120.

As shown in FIGS. 3A and 4A, the pump module 110 further includes at least one first fixing element 117A and at least one second fixing element 117B. When the pump module 110 is connected to the cooling module 120, the first fixing element 117A may fix the first handle 115A to a plate 1053 of the rack module 105 to fix the relative position between the first handle 115A and the rack module 105. At this time, the first pump 113A does not easily separated from the rack module 105. Similarly, when the pump module 110 is connected to the cooling module 120, the second fixing element 117B may fix the second handle 115B on the plate 1053 of the rack module 105 to fix the relative position between the second handle 115B and the rack module 105. At this time, the second pump 113B does not easily separated from the rack module 105. In an embodiment, the first fixing element 117A and the second fixing element 117B are, for example, screw elements, which are detachably connected to the plate 1053.

As shown in FIG. 4B, when the fixing relationship between the first fixing element 117A and the plate 1053 is released, the first handle 115A in FIG. 4B may be rotated (for example, rotated around the-X-axis), so that the first limiting end 115A1 of the first handle 115A disengages from the first engaging element 1052A. As a result, the first handle 115A may be pulled to pull the first sliding plate 111A along the +Y-axis. When the first handle 115A in FIG. 4B is rotated around the +X-axis, the first sliding plate 111A may be pushed toward the-Y-axis and at the same time, the first limiting end 115A1 of the first handle 115A forcibly interferes with and is fixed to the first engaging element 1052A. Similarly, when the fixing relationship between the second fixing element 117B and the plate element 1053 is released, the second handle 115B may be rotated so that the second limiting end (not shown) of the second handle 115B disengages from the second engaging element (not shown). As a result, the second handle 115B may be pulled to pull the second sliding plate 111B along the +Y-axis. When the second handle 115B rotates around the +X-axis, the second sliding plate 111B may be pushed toward the −Y-axis, and at the same time, the second limiting end of the second handle 115B forcibly interferes with and is fixed to the second engaging element.

As shown in FIGS. 3A and 4C1, the pump module 110 further includes at least one third fixing element 118A, at least one fourth fixing element 118B, at least one first stopper 119A, and at least one second stopper 119B. The first stopper 119A is fixed to the first accommodating housing 112A, and the second stopper 119B is fixed to the second accommodating housing 112B. The first stopper 119A has a first fixing hole 119Aa which is a screw hole, and the third fixing element 118A is a threaded element. The third fixing element 118A is detachably connected to the first fixing hole 119Aa. Through the screwing of the third fixing element 118A with the first fixing hole 119Aa, the relative position between the first accommodating housing 112A and the first handle 115A may be fixed. Similarly, the second stopper 119B has a second fixing hole 119Ba, the second fixing hole 119Ba is a screw hole, and the fourth fixing element 118B is a threaded element. The fourth fixing element 118B is detachably connected to the second fixing hole 119Ba. Through the screwing of the fourth fixing element 118B with the second fixing hole 119Ba, the relative position between the second accommodating housing 112B and the second handle 115B may be fixed. The third fixing element 118A and the fourth fixing element 118B are, for example, hand screws, which may pivot the first handle 115A and the second handle 115B to the first accommodating housing 112A and the second accommodating housing 112B, respectively, and may also be manually disassembled when necessary, so that the first handle 115A and the second handle 115B are separated from the first accommodating housing 112A and second accommodating housing 112B.

As shown in FIG. 4A, the first limiting end 115A1 has a first pressing curved surface 115A1s, and the first engaging element 1052A has a second pressing curved surface 1052As. When the first handle 115A and the first sliding plate 111A are substantially perpendicular (for example, the first handle 115A is substantially parallel to Z-axis), the first pressing curved surface 115A1s interferes with the second pressing curved surface 1052As. In addition, as shown in FIG. 6, the cooling cabinet 100 further includes at least one first connector 160A, the first connector 160A is connected to the first pump 113A. The interference force may fasten tightly engage the first connector 160A with the cooling module 120. Similarly, the second limiting end (not shown) of the second handle 115B has the same or similar technical features as the first limiting end 115A1 of the first handle 115A, and the second engaging element has the same or similar technical features as the first engaging element 1052A, and they will not be repeated here. In addition, as shown in FIG. 6, the cooling cabinet 100 further includes at least one second connector 160B, and the second connector 160B is connected to the second pump 113B. The interference force may tightly engage the second connector 160B and the cooling module 120 (fluid path connection), and at the same time, connect the first connector 116A with the connector 120C (electrical-path connection). The connectors 160A and 160B are, for example, quick connectors. The cooling module 120 includes a third connector 120G1 that mates with the first connector 160A and includes a fourth connector 120G2 that mates with the second connector 160B (the fourth connector 120G2 is shown in FIG. 4C2), and they will not be repeated here. The first handle 115A passes through a hole 1051Aa of the first bottom plate 1051A and abuts against the first engaging element 1052A (for example, position-limiting). The first engaging element 1052A may be fixed (for example, locked) on the first bottom plate 1051A, and thus the first engaging element 1052A and the first bottom plate 1051A cannot slide relative to each other, so that the first handle 115A abutting against the first engaging element 1052A is also fixed relative to the first bottom plate 1051A.

As shown in FIG. 4B, although the first handle 115A being in contact with the first engaging element 1052A, the first handle 115A is in a relaxed state (or a release state) at this time. When the first handle 115A is in the relaxed state, the first handle 115A is not tightly fastened to the first engaging element 1052A, and at this time the first connector 160A and the third connector 120G are in the separation state (the fluid path is disconnected), and the first connector 116A and the connector 120C are in the separation state (the electrical-path is disconnected). As shown in FIG. 4A, when the first handle 115A continues to rotate around the +X-axis, that is, in a clockwise direction (for example, using a contact point of the first pressing curved surface 115A1s and the second pressing curved surface 1052As as a fulcrum), the pump module 110 begins to be pushed toward the −Y-axis, and the first connector 160A of the pump module 110 begins to buckle into the third connector 120G1 of the cooling module 120. Then, when the first handle 115A continues to rotate around the +X-axis, the pump module 110 is continuously pushed toward the-Y-axis until the first handle 115A is perpendicular to the XY plane, and the first pressing curved surface 115A1s of the first handle 115A is pressed tightly against the second pressing curved surface 1052As of the first engaging element 1052A (as shown in FIG. 4A). At this time, the first connector 160A is completely buckled with the third connector 120G1 of the cooling module 120 to connect the fluid path. In addition, the operating principle of the second handle 115B is the same as that of the first handle 115A, and it will not be repeated here.

As shown in FIG. 4C1 and 6, the first inverter 114A may be electrically connected to the first connector 116A to receive direct current DC (not shown) from the first connector 116A. The first inverter 114A is electrically connected to the first pump 113A and configured to convert direct current (DC) into alternating current (AC) and supply the AC power to the first pump 113A. Similarly, the second inverter 114B may be electrically connected to the second connector 116B to receive the DC power (not shown) from the second connector 116B. The second inverter 114B is electrically connected to the second pump 113B and configured to convert the direct current into the alternating current and supply the alternating current to the second pump 113B. In addition, the cooling module 120 further includes a plurality of the connectors 120C that mates the first connector 116A and the second connector 116B, and the connectors 120C may be electrically connected to the power supply chassis (not shown) of the cooling cabinet 100. The power supply chassis may receive external power and supply it to various electronic components of the cooling cabinet 100.

In an embodiment, when the pump module 110 and the cooling module 120 change from the separation state to the connection state, the connectors (for example, the first connector 160A and/or the second connector 160B) of the pump module 110 are connected to the corresponding connectors (for example, the third connector 120G1 and/or the fourth connector 120G2) of the cooling module 120, and at the same time, the connectors (for example, the first connector 116A and the second connector 116B) of the pump module 110 are connected to the connectors 120C of the cooling module 120. When the pump module 110 and the cooling module 120 are changed from the connection state to the separation state, the connectors (for example, the first connector 160A and/or the second connector 160B) of the pump module 110 are disconnected from the connector (for example, the third connector 120G1 and/or the fourth connector 120G2) of the cooling module 120 and at the same time, the connectors (for example, the first connector 116A and the second connector 116B) of the pump module 110 are disconnected from the connectors 120C of the cooling module 120. In other words, the fluid path and the electrical-path of the pump module 110 and the cooling module 120 may be connected or disconnected at the same time. In other words, the pump module 110 and the cooling module 120 are hot-swappable.

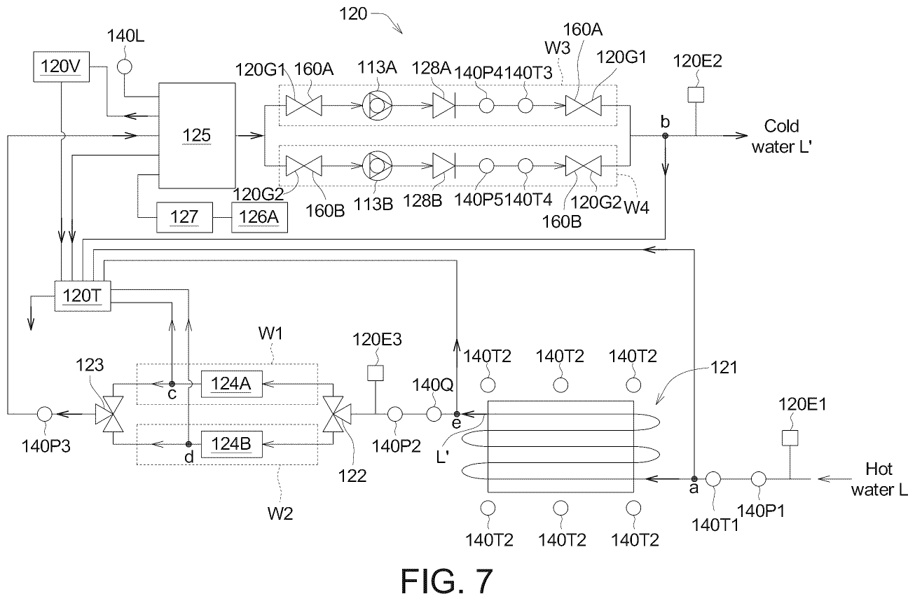

Referring to FIG. 7, FIG. 7 illustrates a schematic diagram of the fluid path of the cooling module 120 in FIG. 1. The cooling module 120 includes a radiator 121, at least one three-way valve (for example, a three-way valve 122 and a three-way valve 123), at least one filter (for example, a first filter 124A and a second filter 124B), a main liquid tank 125, a liquid replenishment tank 126A, a liquid replenishment pump 127, check valves 128A and 128B, a drain valve 120V, a drain tank 120T, and at least one exhaust valve (for example, exhaust valves 120E1 and 120E2). The two components of the cooling module 120 may be connected through at least one liquid pipe and/or at least one connector (for example, a quick connector). The sensor module 140 includes at least one temperature sensor (for example, a temperature sensor 140T1, a temperature sensor 140T2, a temperature sensor 140T3 and a temperature sensor 140T4), at least one pressure sensor (for example, a pressure sensor 140P1, a pressure sensor 140P2, a pressure sensor 140P3, a pressure sensor 140P4 and a pressure sensor 140P5), a liquid level sensor 140L, and a flow sensor 140Q. In addition, a liquid leakage sensor (not shown), such as a liquid leakage detection line, is disposed near the first pump 113B and the second pump 113B. In particular, a configuration density of the liquid leakage detection lines is increased near the first pump 113A and the second pump 113B and the quick connector, for example, the configuration density in the connector area is greater than the configuration density in the area of the first pump 113A and the second pump 113B. These sensors may be electrically connected to the control module 150 through wired technology or wireless technology to transmit the sensed signals to the control module 150. The control module 150 monitors the operation of the cooling cabinet 100 according to these sensing signals.

As shown in FIG. 7, the temperature sensor 140T1 may be disposed in an upstream fluid path of the radiator 121 for sensing a temperature of the hot coolant L, and the pressure sensor 140P1 may be disposed in the upstream fluid path of the radiator 121 for sensing a pressure of the hot coolant L. The temperature sensor 140T2 may be disposed on or around the radiator 121 for sensing the temperature of the radiator 121 itself or a surrounding temperature of the radiator 121. After passing through the radiator 121, the hot coolant L may be cooled into a cold coolant L′. The flow sensor 140Q may be disposed in the fluid path between the radiator 121 and the three-way valve 122 for sensing a flow of the cold coolant L′. The pressure sensor 140P2 may be disposed in the fluid path between the radiator 121 and the three-way valve 122 for sensing a pressure of the cold coolant L′.

As shown in FIG. 7, the first filter 124A is connected to the three-way valves 122 and 123, and the second filter 124B is connected to the three-way valves 122 and 123. The first filter 124A is disposed in a first fluid path W1, and the second filter 124B is disposed in a second fluid path W2, wherein the first fluid path W1 and the second fluid path W2 are arranged in parallel. As a result, when the first filter 124A on the first fluid path W1 is replaced or repaired, the first fluid path W1 may be shut off through the three-way valves 122 and 123, but the second fluid path W2 remains open, so that the cold coolant L′ may still continue to flow downstream through the second fluid path W2. Similarly, when the second filter 124B on the second fluid path W2 is replaced or repaired, the second fluid path W2 may be shut off through the three-way valves 122 and 123, but the first fluid path W1 remains open, so that the cold water L′ may still continue to flow downstream through the first fluid path W1.

As shown in FIG. 7, the pressure sensor 140P3 is disposed between the three-way valve 123 and the main fluid tank 125 for sensing the pressure of the fluid path. The liquid level sensor 140L is connected to the main fluid tank 125 for sensing a liquid level in the main fluid tank 125. The cold fluid L′ may be stored in the main fluid tank 125. The fluid replenishment pump 127 connects the main fluid tank 125 with the fluid replenishment tank 126A. When the amount of fluid in the main fluid tank 125 is insufficient, the fluid replenishment pump 127 may draw fluid from the fluid replenishment tank 126A into the main fluid tank 125. The fluid replenishment pump 127 may be electrically connected to the control module 150, and the control module 150 may decide whether to drive the fluid replenishment pump 127 to operate according to the signal of the liquid level sensor 140L.

As shown in FIG. 7, the first pump 113A, the first connector 160A, the third connector 120G1, the check valve 128A, the pressure sensors 140P4, 140P5 and the temperature sensor 140T3 may be disposed in the third fluid path W3, and the second pump 113B, the second connector 160B, the fourth connector 120G2, the check valve 128B, the pressure sensor 140P5 and the temperature sensor 140T4 may be disposed in the fourth fluid path W4, wherein the third fluid path W3 and the fourth fluid path W4 are arranged in parallel.

As shown in FIGS. 2A, 2C, 2D and 7, hot fluid (for example, water, etc.) L may enter the cooling module 120 from an upper side of the rack module 105 or enter the cooling module 120 from a lower side of the rack module 105, and cold fluid L′ may flow out of the cooling module 120 from the upper side of the rack module 105 or flow out of the cooling module 120 from the lower side of the rack module 105. For example, the cooling module 120 further includes at least one hot fluid pipe PH and at least one cold fluid pipe PC, wherein the hot fluid pipe PH is connected to the radiator 121, and the hot fluid L1 may enter the radiator 121 through the hot fluid pipe PH, and the cold fluid pipe PC is connected to an outlet of the pump, and the cold fluid L′ may flow out of the cooling cabinet 100 through the cold fluid pipe PC. The hot fluid pipe PH has an upper inlet PHa and a lower inlet PHb on the upper side and the lower side of the rack module 105 respectively, and the hot fluid may selectively enter the hot fluid pipe PH from the upper inlet PHa or the lower inlet PHb. The cold fluid pipe PC has an upper outlet PCa and a lower outlet PCb on the upper side and the lower side of the rack module 105 respectively, and the cold fluid L′ may selectively flow out of the cold fluid pipe PC from the upper outlet PCa or the lower outlet PCb.

As shown in FIG. 7, the exhaust valve 120E1 may be connected to the inlet of the hot coolant L (for example, the hot fluid pipe PH) to discharge gas in the hot coolant L. The exhaust valve 120E2 may be connected to the outlet of the cold coolant L′ (for example, the cold fluid pipe PC) to discharge gas in the cold coolant L′. The exhaust valve 120E3 may be connected the upstream (i.e., before filtration) of the filter (for example, the first filter 124A and the second filter 124B) to discharge gas in the cold coolant L′ prior to filtration. In an embodiment, the exhaust valves 120E1, 120E2 and/or 120E3 may be kept open to release gas from the fluid path immediately for avoiding excessive pressure in the fluid path and preventing the pipe from bursting.

As shown in FIG. 7, the drain valve 120V connects the main liquid tank 125 and the drain tank 120T. When the pressure in the main liquid tank 125 exceeds a preset pressure (for example, 6 atmospheres), the drain valve 120V opens to discharge the coolant in the main liquid tank 125 to the drain tank 120T. In addition, the drain tank 120T may be connected to the fluid inlet side “a” of the hot coolant L, the fluid outlet side “b” of the cold fluid L′, the main liquid tank 125, the liquid outlet side “c” of the first filter 124A, the liquid outlet side “d” of the second filter 124B, and the liquid outlet side “e” of the radiator 121. Such “full drain design” may drain the liquid in the fluid path for preventing the liquid from flowing in the cabinet and affecting other elements. Although not shown, the fluid path between the fluid inlet side “a” of the hot fluid L and the drain tank 120T, the fluid path between the fluid outlet side “b” of the cold coolant L′ and the drain tank 120T, the fluid path between the main liquid tank 125 and the drain tank 120T, the fluid path between the fluid outlet side “c” of the first filter 124A and the drain tank 120T, the fluid path between the liquid outlet side “d” of the second filter 124B and the drain tank 120T, and the fluid path between the fluid outlet side “e” of the radiator 121 and the drain tank 120T may be provided with ball valves. When the ball valve is opened, the liquid in the fluid path is allowed to flow into the drain tank 120T.

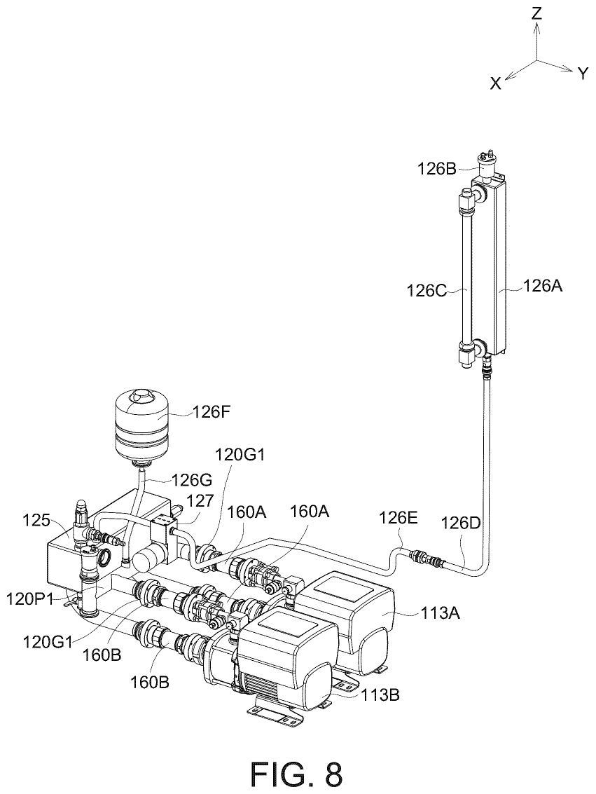

As shown in FIGS. 7 and 8, FIG. 8 illustrates a fluid path configuration diagram of the main liquid tank 125, the liquid replenishment tank 126A, the liquid replenishment pump 127 and an expansion liquid tank 126F in FIG. 7. The cooling module 120 further includes a breathing valve 126B, a liquid level gauge 126C, a first liquid pipe 126D, a second liquid pipe 126E, an expansion liquid tank 126F and a third liquid pipe 126G. The first liquid pipe 126D is connected to a liquid outlet of the liquid replenishment tank 126A, and the second liquid pipe 126E is connected to the liquid replenishment pump 127. The liquid replenishment pump 127 is connected to the main liquid tank 125. The first liquid pipe 126D may be selectively connected or separated from the second liquid pipe 126E. When the liquid in the liquid replenishment tank 126A needs to be replenished, the first liquid pipe 126D may be disconnected from the second liquid pipe 126E and connected to a liquid source (not shown) so that the liquid in the liquid source may be replenished into the liquid replenishment tank 126A. The aforementioned liquid source is, for example, a liquid supply truck. When the liquid in the main liquid tank 125 needs to be replenished, the first liquid pipe 126D may be connected to the second liquid pipe 126E. In addition, the first liquid pipe 126D and the second liquid pipe 126E may be connected through a quick connector. The breathing valve 126B may be connected to a top of the liquid replenishment tank 126A, and the breathing valve 126B may be kept open to immediately discharge the gas in the liquid replenishment tank 126A. The liquid level gauge 126C is connected to the liquid replenishment tank 126A, and the liquid level gauge 126C may show the liquid level in the liquid replenishment tank 126A. As a result, the liquid level of the liquid replenishment tank 126A may be known by observing the liquid level of the liquid level gauge 126C.

As shown in FIGS. 7 and 8, the third liquid pipe 126G connects the expansion liquid tank 126F and the liquid outlet pipe 120P1. The liquid outlet pipe 120P1 is connected to the liquid outlet of the pump. The liquid in the expansion liquid tank 126F may adjust the pressure and temperature fluctuations of the liquid outlet of the pump to stabilize the liquid pressure.

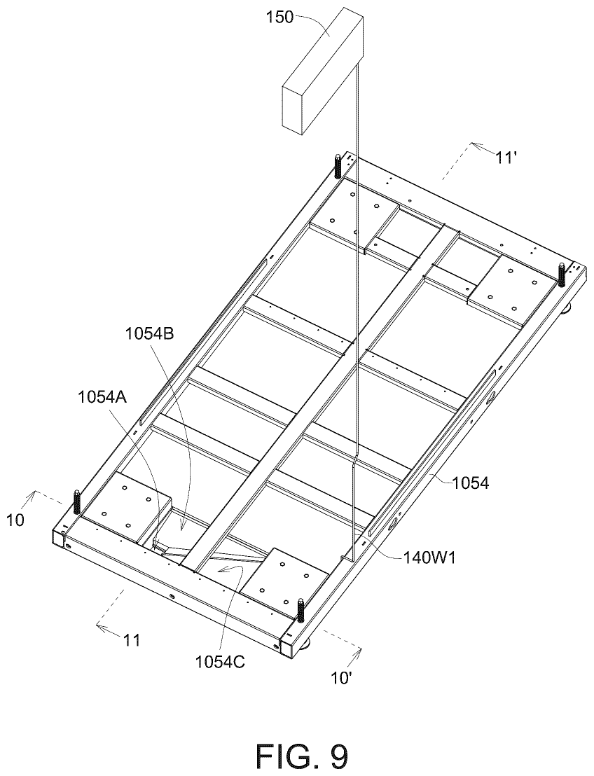

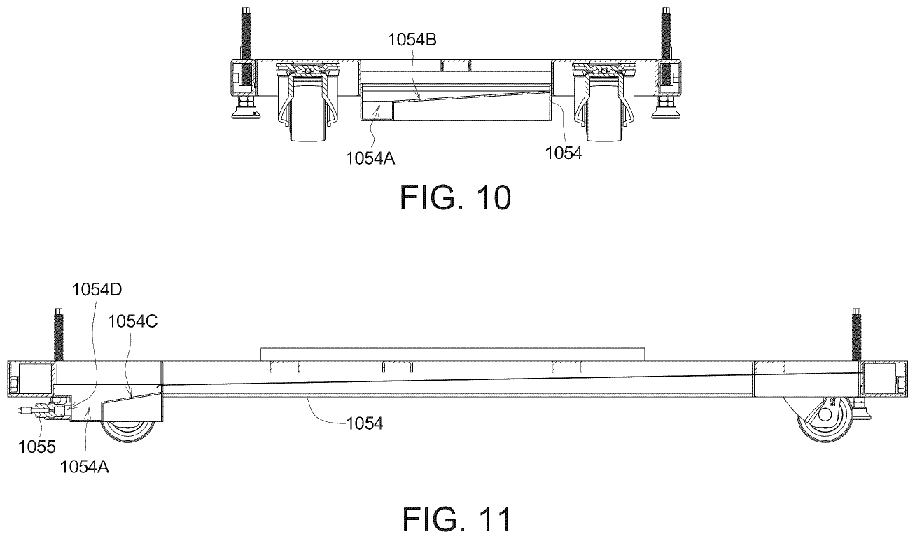

Referring to FIGS. 9 to 11, FIG. 9 illustrates a schematic diagram of a base 1054 of the rack module 105 in FIG. 2A, FIG. 10 illustrates a schematic diagram of a cross-sectional view of the base 1054 of the rack module 105 in FIG. 9 along a direction 10-10′, and FIG. 11 illustrates a schematic diagram of a cross-sectional view of the base 1054 of the rack module 105 in FIG. 9 along a direction 11-11′.

As shown in FIGS. 9 to 11, the pump module 110 may be disposed on the base 1054. The base 1054 includes a leakage tank 1054A and at least one liquid guide surface (for example, a first liquid guide surface 1054B and a second liquid guide surface 1054C), wherein the first liquid guide surface 1054B and the second liquid guide surface 1054C are connected to the leakage tank 1054A and are configured to guide the leakage to the leakage tank 1054A. The first liquid-guiding surface 1054B and the second liquid-guiding surface 1054C are, for example, inclined from high to low toward the leakage tank 1054A, so that the leaked liquid can quickly flow into the leakage tank 1054A. In addition, the base 1054 has a drainage channel 1054D which is connected to the leakage tank 1054A and an outer side of the base 1054. The rack module 105 further includes a drain valve 1055, and the drain valve 1055 is connected to the drainage channel 1054D. When the drain valve 1055 is opened, the leaked liquid in the leakage tank 1054A may be discharged to the outside of the cooling cabinet 100.

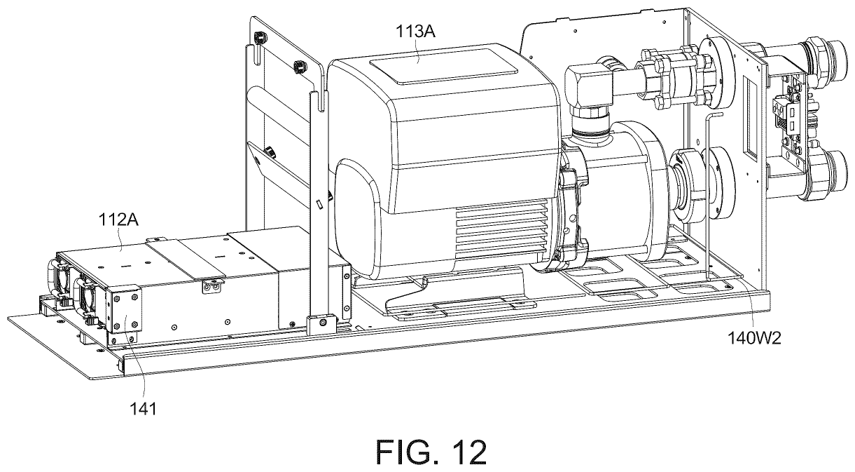

Referring to FIGS. 9 and 12, FIG. 12 illustrates a schematic diagram of the configuration of the second liquid leakage detection line 140W2 according to an embodiment of the present invention. The sensor module 140 further includes a first liquid leakage detection line 140W1 and a second liquid leakage detection line 140W2 which may be electrically connected to the control module 150. The first liquid leakage detection line 140W1 and the second liquid leakage detection line 140W2 may sense the liquid leakage and transmit the signals to the control module 150. As shown in FIG. 9, the first liquid leakage detection line 140W1 is located in the base 1054 and extends to the liquid guide surface (for example, the first liquid guide surface 1054B and/or the second liquid guide surface 1054C) and the leakage tank 1054A. As shown in FIG. 12, the second liquid leakage detection line 140W2 is located on the first sliding plate 111A and surrounds the first pump 113A. In addition, the sensor module 140 further includes a third liquid leakage detection line (not shown) which is located on the second sliding plate 111B and surrounds the second pump 113B.

As shown in FIG. 12, the sensor module 140 further includes an indicator light 141 which is electrically connected to the control module 150. The indicator light 141 may indicate a status of the pump, such as an operating status, a fault status, etc.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A cooling cabinet, comprising:
a rack module, comprising a first bottom plate and a first engaging element, wherein the first engaging element is fixed to the first bottom plate;
a cooling module, disposed in the rack module; and
a pump module, disposed in the rack module and selectively connected with or disconnected from the cooling module, and comprising:
a first sliding plate, slidably connected to the first bottom plate;
a pivot device, disposed on the first sliding plate;
a first pump, disposed on the first sliding plate; and
a first handle, pivotally connected to the pivot device and comprising a first limiting end;
wherein when the pump module is connected to the cooling module, the first limiting end of the first handle interferes with the first engaging element.

2. The cooling cabinet as claimed in claim 1, wherein the first limiting end of the first handle has a first pressing curved surface, the first engaging element has a second pressing curved surface, and the first pressing curved surface interferes with the second pressing curved surface when the first handle is perpendicular to the first sliding plate.

3. The cooling cabinet as claimed in claim 1, wherein when the pump module and the cooling module are connected, a fluid path and an electrical-path between the pump module and the cooling module are connected at the same time.

4. The cooling cabinet as claimed in claim 1, wherein when the pump module and the cooling module are separated, a fluid path and an electrical-path between the pump module and the cooling module are separated at the same time.

5. The cooling cabinet as claimed in claim 1, wherein the pump module further comprises a fixing element; when the pump module and the cooling module are connected, the fixing element is fixed to a plate of the rack module.

6. The cooling cabinet as claimed in claim 1, wherein the pump module further comprises a first accommodating housing, a fixing element and a stopper, the stopper is fixed to the first accommodating housing and has a fixing hole; when the pump module the cooling module are disconnected, the fixing element is fixed to the fixing hole.

7. The cooling cabinet as claimed in claim 1, wherein the rack module further comprises a base, and the pump module is disposed on the base; the base comprises a leakage tank and a liquid guide surface, and the liquid guide surface is inclined from high to low toward the leakage collection tank.

8. The cooling cabinet as claimed in claim 7, further comprising:
a first liquid leakage detection line, located in the base and extending to the liquid guide surface and the leakage tank.

9. The cooling cabinet as claimed in claim 1, further comprising:
a second liquid leakage detection line, located on the first sliding plate and surrounding the first pump.

10. The cooling cabinet as claimed in claim 1, wherein the cooling module comprises:
a first filter; and
a second filter, connected with the first filter in parallel.

11. The cooling cabinet as claimed in claim 1, wherein the rack module further comprises a second bottom plate and a second engaging element, wherein the second engaging element is fixed to the second bottom plate; the pump module further comprises:
a second sliding plate, slidably connected to the second bottom plate;
a second accommodating housing;
a second pump, disposed on the second sliding plate; and
a second handle, pivotally connected to the second accommodating housing and comprising a second limiting end;
when the pump module is connected to the cooling module, the second limiting end of the second handle interferes with the second engaging element.

12. The cooling cabinet as claimed in claim 1, wherein the cooling module further comprises:
a main liquid tank;
a liquid replenishment tank; and
a liquid replenishment pump, connecting the liquid replenishment tank with the main liquid tank and configured to:
draw liquid from the liquid replenishment tank into the main liquid tank when the liquid level in the main liquid tank is insufficient.

13. The cooling cabinet as claimed in claim 12, wherein the cooling module further comprises:
a liquid level gauge connected to the liquid replenishment tank to display a liquid level in the liquid replenishment tank.

14. The cooling cabinet as claimed in claim 12, wherein the cooling module further comprises:
a first liquid pipe, connected to a liquid outlet of the liquid replenishment tank; and
a second liquid pipe, connected to the liquid replenishment pump;
wherein the first liquid pipe is selectively connected to or separated from the second liquid pipe.

15. The cooling cabinet as claimed in claim 1, wherein the cooling module further comprises:
an expansion liquid tank; and
a third liquid pipe, connecting the expansion liquid tank with a liquid outlet of the first pump.

16. The cooling cabinet as claimed in claim 1, wherein the pivot device comprises:
a fixing box, fixed to the first sliding plate; and
a pivot element, fixed to the first handle and pivotally connected to the fixing box.

17. The cooling cabinet as claimed in claim 16, wherein the pivot device comprises:
a limiting element, fixed to the pivot element;
wherein the limiting element and the pivot element are respectively located on two opposite sides of the fixing box.

18. The cooling cabinet as claimed in claim 16, wherein the pivot device comprises:
a fixing element, fixing a relative position between the fixing box and the first sliding plate.
